(19) United States
(12) Patent Application Publication
(10) Pub. No.: US 2021/0172565 A1
(43) Pub. Date: Jun. 10, 2021

(54) BRACKET DEVICE FOR USE WITH A PANEL

(71) Applicant: Robert Dempsey, Kent, WA (US)

(72) Inventor: Robert Dempsey, Kent, WA (US)

(21) Appl. No.: 16/704,173

(22) Filed: Dec. 5, 2019

(51) Int. Cl. F16M 13/02; H05K 5/02

(52) U.S. Cl. CPC F16M 13/02; H05K 5/0017; H05K 5/0217

(57) ABSTRACT

A bracket for use with a panel is disclosed herein. The bracket device includes rectangular-shaped right and left side surfaces along with a rectangular-shaped top side surface. The top side surface extends perpendicularly from the right side surface to the left side surface, holding the right and left side in parallel relation. The device is useful for mounting the panel onto a desired surface.

### FIELD OF THE INVENTION

The present disclosure relates generally to supports and more particularly to a panel mounting bracket support.

### BACKGROUND OF THE INVENTION

An electrical enclosure is a cabinet for electrical or electronic equipment to mount switches, knobs and displays and to prevent electrical shock to equipment users and protect the contents from the environment. The enclosure is often the only part of the equipment which is not seen by users. It may be designed not only for its utilitarian requirements, but also to be pleasing to the eye. Electronic packaging may place many demands on an enclosure for heat dissipation, radio frequency interference and electrostatic discharge protection, as well as functional, esthetic and commercial constraints.

Some electrical panels require specialized enclosures or mounts depending on the application. Some vehicles, such as boats, RVs, airplanes, and cars may require aftermarket housings or brackets in order to retrofit the existing vehicle with upgraded or expanded parts. Adding new parts or electrical systems to a vehicle may often necessitate the addition of new switches to operate those systems. These new switches may typically be provided in the form of a panel or housing. Not every vehicle has the space or mounting surfaces needed to include such upgrades. A suitable solution is desired.

### BRIEF DESCRIPTION OF THE DRAWINGS

FIG. 1 is an upper perspective view of a panel mounted onto a bracket for use with a panel, according to an embodiment of the present disclosure.

FIG. 2 is a perspective view of the bracket without a panel attached thereto, according to an embodiment of the present disclosure.

### DETAILED DESCRIPTION

Reference will now be made in detail to the present preferred embodiments, examples of which are illustrated in the accompanying drawings.

The object of this disclosure generally includes a bracket for control and display panels. The bracket may include a sturdy support structure with at least 3 walls that may be configured to hold, support and partially enclose a display or operating panel. The display and/or operating panel may include monitors, switches, buttons and the like. The bracket may be used in a variety of applications, but may be especially useful for vehicles including boats, automobiles, RVs, airplanes and possibly home uses such as on shelves, desks, walls or entertainment units.

The bracket may specifically include a metal support shell for use with a 6-inch gang waterproof rocker switch panel. The bracket may help to enable and simplify the installation of such panel into a vehicle or other desired surface by possibly eliminating the need for cutting large holes and allowing flush-mount installation to occur. The bracket may also be configured for easier removal of the panel mounted within the bracket, thereby increasing the efficiency of repairs and other upgrades. In a typical embodiment, the bracket of this disclosure may measure approximately 4¾ inches tall, 7¼ inches long and 3½ inches wide. A preferred embodiment may also include a support bar extending from corner to corner on the bottom of the device face. The bracket of this disclosure may also be configured for customized applications and individual specifications.

The bracket may be configured to mount a variety of panel types. The bracket may specifically be useful for mounting a control panel, a display panel, a rocker switch panel. Materials and configurations may vary depending on applications, but the bracket device for use with a panel of this disclosure may typically be constructed from a metal.

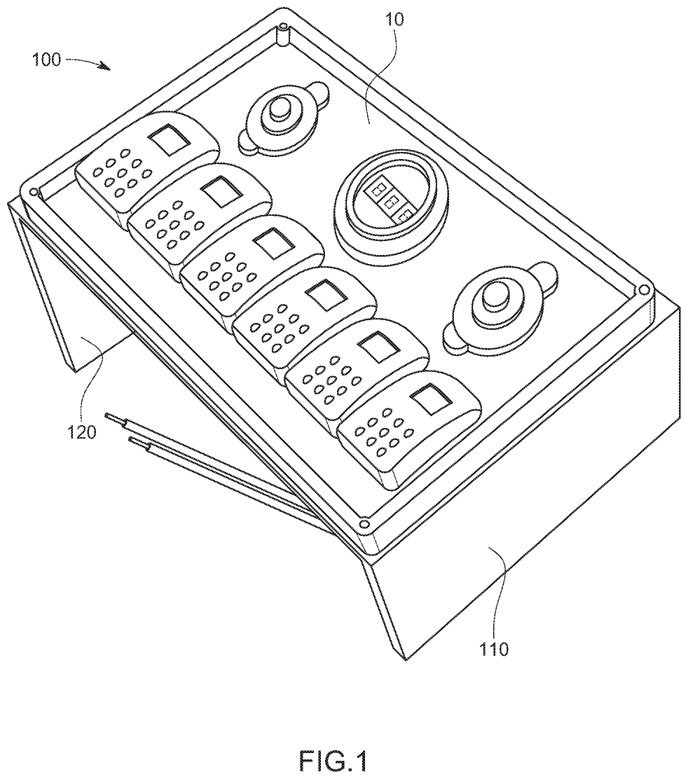

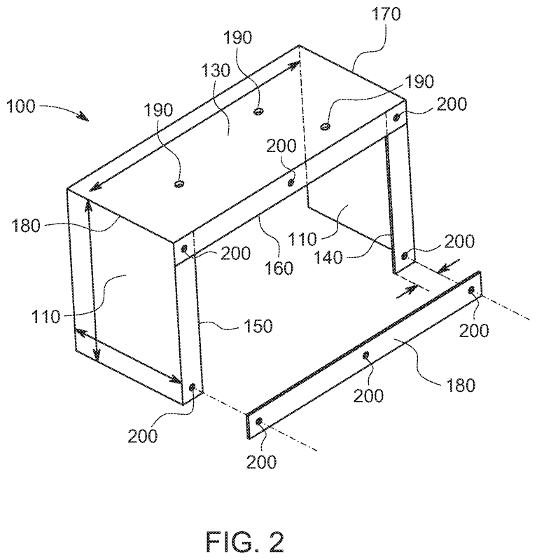

Referring now to FIG. 1, there is shown an upper perspective view of a panel mounted onto a bracket 100 (not numbered here; see FIG. 2) for use with a panel 10. The bracket 100 may include a right side surface 110 having a substantially rectangular shape. The bracket 100 may also include a left side surface 120 having a substantially rectangular shape. The right side surface 110 and left side surface 120 may be arranged in a parallel configuration.

FIG. 1 also shows the panel 10 supported on all sides by an upper edge of each of the right side surface 110 and left side surface 120. The upper edge of the right side surface 170 may be connected with the upper edge of the top side surface 130, which in turn is connected to the upper edge of the left side surface 180. The top side surface 130 may have 3 apertures, 190, that are arranged in a triangular pattern for mounting to a secure surface.

Referring now to FIG. 2, there is shown a perspective view of the bracket 100 without a panel 10 (see FIG. 1) attached thereto. The bracket 100 may include a right-side-surface lip portion 140 extending from an edge of the right-side surface. Similarly, the bracket 100 may include a left-side-surface lip portion 150 extending from an edge of the left-side surface. Yet again, the bracket 100 may include a top-side-surface lip portion 160 extending from an edge of the top-side surface.

Each of the right-side-surface lip portion 140, left-side-surface lip portion 150, and top-side-surface lip portion 160 may include at least one aperture 200. In a preferred embodiment, the right-side-surface lip portion 140 may include 2 apertures, while the left-side-surface lip portion 150 may include 2 apertures and the top-side-surface lip portion 160 may include 3 apertures. In another embodiment, each of the sides of the bracket may have 3 apertures. Also, optional removable bar 180 may have 3 apertures. Each of the apertures 200 referred to herein may be configured to receive a fastening means. The fastening means used may vary by application, but may include screws, bolts, rivets, connectors, nuts, glue and the like.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A bracket for use with a panel, said bracket comprising:
a right-side surface, said right-side surface having a substantially rectangular shape;
a left-side surface, said left-side surface having a substantially rectangular shape and wherein said left-side surface is parallel to said right-side surface;
a top-side surface, said top-side surface having a substantially rectangular shape and wherein said top-side surface extends from said right-side surface to said left-side surface and wherein said top-side surface is perpendicular to said right-side surface and left-side surface;
wherein each of said right-side surface, left-side surface, and top-side surface has a lip portion extending from an edge of each of said right-side surface, left-side surface, and top-side surface; and
wherein said bracket is configured to mount said panel onto a desired sturdy frame.

2. The bracket of claim 1, wherein said panel is a control panel.

3. The bracket of claim 1, wherein said panel is a display panel.

4. The bracket of claim 1, wherein said panel is a rocker switch.

5. The bracket of claim 1, wherein said bracket is approximately 4.75 inches in height.

6. The bracket of claim 1, wherein said bracket is approximately 7.25 inches in length.

7. The bracket of claim 1, wherein said bracket is approximately 3.5 inches in width.

8. The bracket of claim 1, wherein said bracket is made of metal.

9. The bracket of claim 1, wherein said desired surface is located in an automobile.

10. The bracket of claim 1, wherein said desired surface is located in a boat.

11. The bracket of claim 1, wherein said desired surface is located in a recreational vehicle.

12. The bracket of claim 1, wherein said desired surface is located on a shelf.

13. The bracket of claim 1, wherein said desired surface is located on a desk.

14. The bracket of claim 1, wherein said desired surface is located on a wall.

15. The bracket of claim 1, wherein said right-side-surface lip portion has 2 apertures, each of said 2 apertures configured to receive a fastening means.

16. The bracket of claim 1, wherein said left-side-surface lip portion has 2 apertures, each of said 2 apertures configured to receive a fastening means.

17. The bracket of claim 1, wherein said top-side-surface lip portion has 3 apertures, each of said 3 apertures configured to receive a fastening means.
